(19) United States
(12) Patent Application Publication
(10) Pub. No.: US 2008/0002749 A1
(43) Pub. Date: Jan. 3, 2008

(54) Material processing method for semiconductor lasers

(75) Inventors: Axel Scherer, Laguna Beach, CA (US); Norman Sze-Keung Kwong, San Marino, CA (US); Tirong Chen, Azusa, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignees: California Institute of Technology, Pasadena, CA (US); Archcom Technology, Inc., Azusa, CA (US)

(21) Appl. No.: 11/238,843

(22) Filed: Sep. 28, 2005

Related U.S. Application Data
(60) Provisional application No. 60/614,207, filed on Sep. 29, 2004.

(51) Int. Cl. H01S 5/00; H01S 3/06; G02B 6/12; H01S 3/07

(52) U.S. Cl. 372/50.1; 372/66; 385/14

(57) ABSTRACT

Embodiments in accordance with the present invention relate to the use of precise etching techniques in the construction of high quality lasers. In accordance with one embodiment of the present invention, Focused Ion Beam Etching (FIBE) of a semiconductor stripe in a multi-mode edge-emitting Fabry-Perot (FP) laser may allow the rapid and effective fabrication of a single mode laser and/or a surface emitting laser. The use of FIBE or other precise etching techniques allows precise control over the dimension, angle, and orientation of etched features, and offers extremely smooth surfaces that reduce optical loss in the resulting device.

### CROSS-REFERENCES TO RELATED APPLICATIONS

This application claims priority to U.S. Provisional patent application No. 60/614,207 filed Sep. 29, 2004 and hereby incorporated by reference for all purposes.

### STATEMENT AS TO RIGHTS TO INVENTIONS MADE UNDER FEDERALLY SPONSORED RESEARCH OR DEVELOPMENT

Work described herein has been supported in part by the Defense Advanced Research Projects Agency (DARPA) (Sponsor Award No. HR0011-04-1-0054). The United States Government may therefore have certain rights in the invention.

### BACKGROUND OF THE INVENTION

Embodiments in accordance with the present invention relate to processing methods for forming optical devices. More particularly, certain embodiments in accordance with the present invention relate to forming precise features in a semiconductor material. In one specific example, a single mode laser may be fabricated from a multi-mode laser by forming a cut having precise dimensions and resulting in low surface roughness.

Semiconductor lasers currently enjoy widespread use for a large number of applications. FIG. 1 shows a simplified end view of a conventional edge emitting semiconductor laser structure 100. Conventional edge emitting laser 100 features substrate 102 having waveguide 104. The conventional edge emitting laser 100 typically has a length of about 300 μm.

During conventional fabrication of the edge emitting laser, the substrate bearing the waveguide is physically cleaved to expose the waveguide at the edge. Light 106 is emitted from waveguide 104 at cleaved edge 102a of substrate 102, in a direction parallel to surface 102b of substrate 102.

While useful for certain applications, the conventional edge emitting semiconductor laser offers certain disadvantages. For example, this conventional laser design exhibits a multi-mode emission which not suitable for long distance communications applications. Single wavelength lasers, such as Distributed Feedback (DFB) lasers can be fabricated, but with relatively high expense and low yield. Also, the cost of edge emitting lasers tends to be higher than surface emitting lasers (see below), because edge emitting lasers need to be cleaved before testing, whereas surface emitting lasers can use automatic wafer scale testing tools. Moreover, light emitted from the edge may be reflected from facets at the point of cleaving, thereby degrading the quality of output of the laser. Finally, the laser occupies a relatively large area on the substrate, which may limit its incorporation into array structures.

In certain applications, it may be advantageous for light to be emitted in a single mode from a semiconductor laser in a direction oriented perpendicular (vertical) relative to the substrate. Accordingly, FIG. 2 shows a simplified perspective view of a conventional Vertical Cavity Surface Emitting Laser (VCSEL) semiconductor laser structure 200. Conventional VCSEL structure 200 includes substrate 202 bearing a plurality of layers of material 204 exhibiting alternating high and low refractive indices. FIG. 2 indicates the direction of emission of light 206 to be perpendicular to the substrate 202. The conventional VCSEL structure shown in FIG. 2 has a lateral dimension of only about 5 μm, allowing its integration into dense arrays.

The layers of the conventional VCSEL are typically carefully deposited with a thicknesses of nλ/4, where n is an integer and λ is the wavelength of the emitted light. The number of periods required, and the bandwidth for a given reflectivity depends upon the contrast in refractive indices between the alternating layers. The ultimate reflectivity of the resulting quarter wave mirror depends upon scattering and absorption losses.

While suited for a variety of applications, conventional long wave VCSEL devices may offer certain drawbacks. For example, by requiring the successive deposition of alternating layers of different materials at precise thicknesses, fabrication of a conventional VCSEL may be time consuming and expensive. Moreover, a conventional VCSEL may exhibit relatively low optical power because of the short overall gain cavity offered by the overall thickness of the plurality of thin deposited layers. Another issue associated with many long-wave VCSEL material systems (such as GaN materials), is difficulty lasing at wavelength shorter than 1310 nm, due to reliability issues.

Accordingly, there is a need in the art for improved methods for fabricating semiconductor lasers.

### BRIEF SUMMARY OF THE INVENTION

Embodiments in accordance with the present invention relate to the use of precise etching techniques in the construction of high quality lasers. In accordance with one embodiment of the present invention, Focused Ion Beam Etching (FIBE) of a semiconductor stripe in a multi-mode edge-emitting Fabry-Perot (FP) laser may allow the rapid and effective fabrication of a single mode laser and/or a surface emitting laser. The use of FIBE or other precise etching techniques allows precise control over the dimension, angle, and orientation of etched features, and offers extremely smooth surfaces that reduce optical loss in the resulting device.

An embodiment of a semiconductor laser device in accordance with the present invention comprises, a substrate including a diode in optical communication with a waveguide, the waveguide oriented along a plane of the substrate. A cut in a surface of the substrate extends through the waveguide, the cut forming a first cavity and a second cavity, the cut exhibiting a surface roughness of λ/10 or less, where λ comprises a wavelength of a single mode of light emitted from the diode and optically communicated from the first cavity to the second cavity.

An embodiment of a method in accordance with the present invention for fabricating a single mode laser, comprises, providing a substrate including a diode in optical communication with a waveguide, the waveguide oriented along a plane of the substrate. A cut is formed in a surface of the substrate utilizing a precision etching technique, the cut extending through the waveguide to form a first cavity and a second cavity, the cut exhibiting a surface roughness of λ/10 or less, where λ comprises a wavelength of a single mode of light emitted from the diode and optically communicated from the first cavity to the second cavity.

Another embodiment of a method in accordance with the present invention for fabricating a single mode laser, comprises, providing a Fabry-Perot edge emitting multi-mode laser having a waveguide. A cut is formed through the waveguide utilizing a precision etching technique to form a first cavity and a second cavity, the cut exhibiting a surface roughness of λ/10 or less, where λ comprises a wavelength of a single mode of light emitted from a diode optically coupled with the waveguide and optically communicated from the first cavity to the second cavity.

Various additional objects, features and advantages of the present invention can be more fully appreciated with reference to the detailed description and accompanying drawings that follow.

### BRIEF DESCRIPTION OF THE DRAWINGS

FIG. 1 is a simplified end view of a conventional edge emitting semiconductor laser structure.

FIG. 2 is a simplified perspective view of a conventional VCSEL device.

FIG. 3 shows a simplified cross-sectional view of an embodiment of a coupled cavity laser in accordance with the present invention defined with a focused ion beam cut.

FIG. 3A shows an electron micrograph of a plan view of a FIBE cut of the fabricated device of FIG. 3.

FIG. 3B shows a spectrum of emission intensity versus wavelength for a coupled cavity laser fabricated in accordance with an embodiment of the present invention.

FIG. 3C shows an electron micrograph of a focused ion beam cut in a workpiece, with the rectangular section on the bottom end of the cut enabling measurement of the depth of, and observation of the profile of, the etched facet.

FIG. 4A is a simplified schematic cross-sectional diagram contrasting output of a laser fabricated in accordance with an embodiment of the present invention, with a conventional edge emitting FP laser.

FIG. 4B is an electron micrograph showing a simplified plan view of a FIBE on the FP laser.

FIG. 4C plots output optical power versus laser current for the fabricated single mode laser.

FIG. 4D is a multimode output spectrum of the FP laser prior to the etching to from the single mode laser in accordance with an embodiment of the present invention.

FIG. 4E is a single mode output spectrum of the FP laser after precision etching in accordance with an embodiment of the present invention.

FIG. 4F plots peak wavelength output by the single mode laser versus temperature.

FIG. 4G plots peak wavelength output by the single mode laser versus laser injection current.

FIG. 4H plots side mode suppression ratio versus laser current for the single mode laser.

FIG. 4I shows 2.5 Gb/s transmission “eye” pattern of Nanofab laser for 0 km fiber (back-to-back).

FIG. 4J shows 2.5 Gb/s transmission “eye” pattern of Nanofab laser after 20 km single mode fiber.

FIG. 4K shows 2.5 Gb/s transmission “eye” pattern of standard multimode FP laser for 0 km fiber (back-to-back).

FIG. 4L shows 2.5 Gb/s transmission “eye” pattern of standard multimode FP laser after 20 km single mode fiber (not acceptable for 20 km transmission).

FIG. 5A shows a simplified schematic view of a system for use in FIBE to fabricate an optical device in accordance with an embodiment of the present invention.

FIG. 5B shows a simplified enlarged cross-sectional view of the use of FIBE to form features of an optical device in accordance with an embodiment of the present invention.

FIG. 6 shows a simplified cross-sectional view of a semiconductor laser stripe etched to exhibit a feature in accordance with one embodiment of the present invention.

FIG. 7 shows a simplified cross-sectional view of a semiconductor laser stripe etched to exhibit a feature in accordance with an alternative embodiment of the present invention.

FIG. 8 is a simplified schematic diagram illustrating cross-sectional views of an edge emitting laser converted into a surface emitting DFB laser at an angle of θ as a result precision etching in accordance with an embodiment of the present invention.

FIG. 8A shows a plan view of an electron micrograph of a laser stripe modified by focused ion beam cutting.

FIG. 8B shows an enlarged electron micrograph of a laser stripe bearing an angled mirror etched in accordance with an embodiment of the present invention.

FIG. 8C shows an electron micrograph showing a cross-sectional view of the FIBE on a DFB laser.

FIG. 8D shows a measured beam profile of the surface emitting DFB laser in accordance with an embodiment of the present invention.

FIG. 8E plots output optical power of the surface emitting DFB laser in accordance with an embodiment of the present invention.

FIG. 8F shows the optical spectrum of a surface emitting DFB laser in accordance with an embodiment of the present invention.

FIGS. 9A-B show plan, and enlarged plan views, respectively, of a substrate containing a plurality of laser stripe waveguides.

FIG. 10A shows a cross-sectional electron micrograph of a 45° mirror etched by CAIBE utilizing a beam of Ar+ ions.

FIG. 10B shows a simplified cross-sectional view of forming a cut in a substrate utilizing the CAIBE technique.

FIG. 10C shows an electron micrograph of the dependence of etch depth of a 45° cut etched by CAIBE, versus the width of the cut.

FIG. 11 is an electron micrograph showing a cross-section of a FIBE cut exhibiting a curved profile in accordance with an embodiment of the present invention.

FIG. 12 shows a simplified schematic view of an embodiment of a semiconductor waveguide in accordance with the present invention cut to exhibit a channel to create laser and photo-detector sections.

FIGS. 13A-B show simplified plan and cross-sectional views, respectively, of an embodiment of a low threshold, high speed laser fabricated according to an embodiment of the present invention.

FIG. 13C plots power versus current for the fabricated laser of FIGS. 13A-B.

FIG. 13D plots response versus frequency at different bias currents, for the short cavity laser of FIGS. 13A-B.

FIG. 14A shows a simplified cross-sectional view of one embodiment a DBR application for optical devices fabricated in accordance with an embodiment of the present invention. FIG. 14B shows an electron micrograph of the embodiment of FIG. 14A.

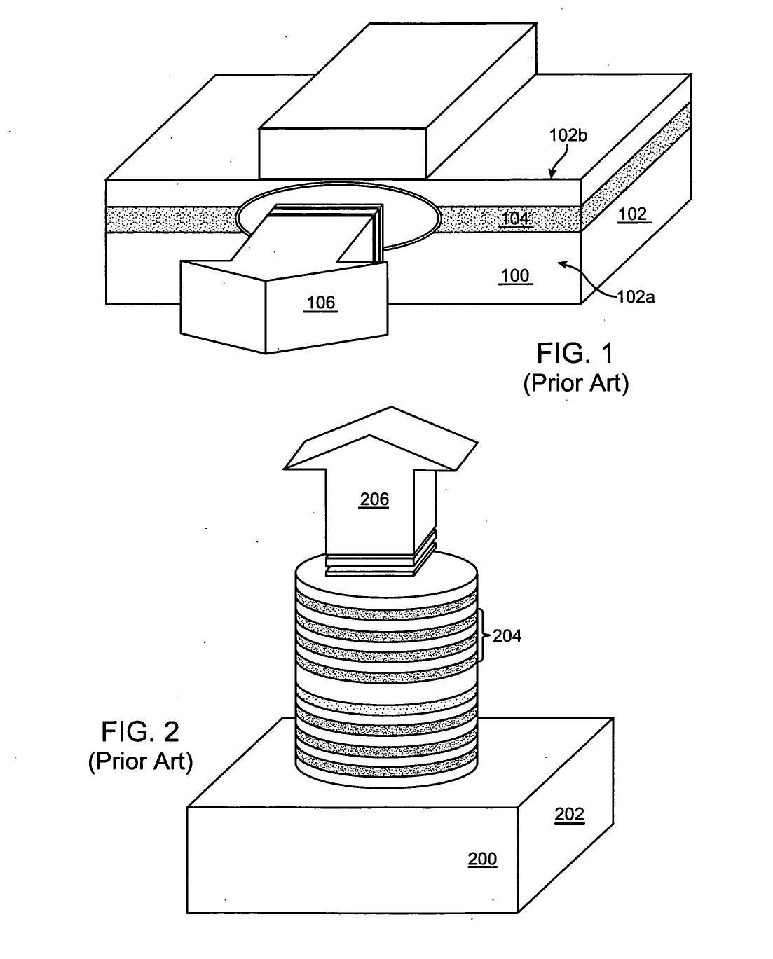

### DETAILED DESCRIPTION OF THE INVENTION

Embodiments in accordance with the present invention relate to the use of precise etching techniques in the construction of high quality lasers. In accordance with one embodiment of the present invention, Focused Ion Beam Etching (FIBE) of a semiconductor stripe in a multi-mode edge-emitting Fabry-Perot (FP) laser may allow the rapid and effective fabrication of a single mode laser and/or a surface emitting laser. The use of FIBE or other precise etching techniques allows precise control over the dimension, angle, and orientation of etched features, and offers extremely smooth surfaces that reduce optical loss in the resulting device.

An embodiment of a process in accordance with the present invention utilizes a focused ion beam, such as a focused beam of Gallium ions, to etch pre-designed shapes and cut channels into semiconductor laser stripes in order to produce the desired effects of light emission. Optical devices fabricated in accordance with embodiments of the present invention offer spectral output characteristics optimal for data- and telecommunications. Using FIBE of conventional laser stripes, single wavelength lasers, and surface emitting lasers (including vertical emitting lasers) have been demonstrated.

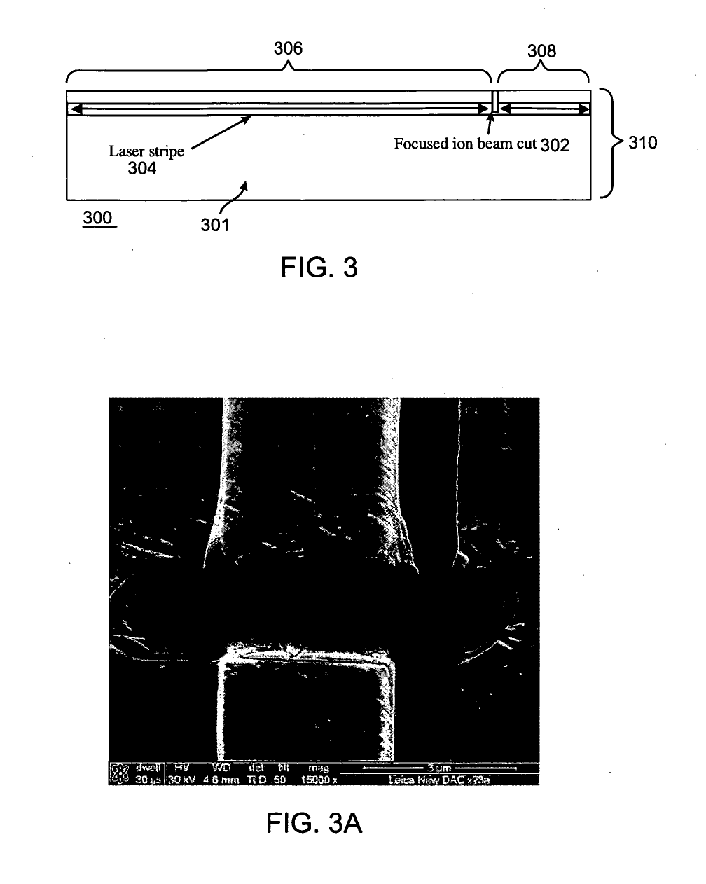

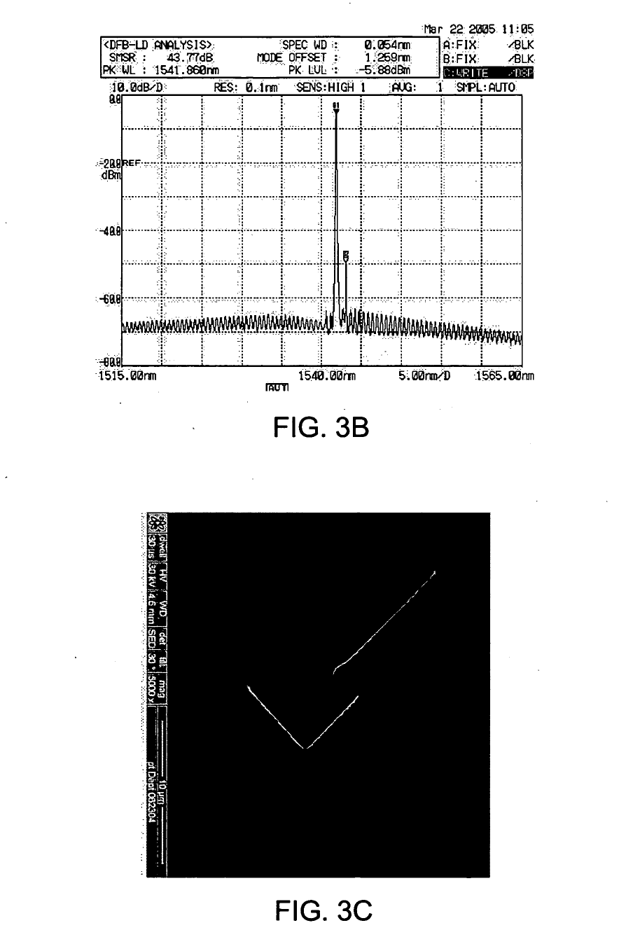

One important application for the use of precision etching techniques in the fabrication of optical devices is to make “coupled cavity laser”. FIG. 3 shows a simplified cross-sectional view of an embodiment of a coupled cavity laser 300 in accordance with the present invention. Coupled cavity laser 300 comprises substrate 310 including semiconductor stripe 304 (also referred to herein as a waveguide or active region). Coupled cavity laser 300 comprises a diode 301 in optical communication with the optical stripe/waveguide 304. Substrate 310 may comprise multiple layers, and may include materials such as InP, InGaAs or InGaAsP, GaAs and AlGaAs, or InGaP and InGaAlP, or InGaN and AlGaN, depending on the emission wavelength desired.

The coupled cavity laser of FIG. 3 is defined with a focused ion beam cut 302 which extends through the semiconductor stripe 304. In accordance with certain embodiments of the present invention, it is preferred that this cut be substantially vertical, that is within about +/−6° of normal from the plane of the substrate, and preferably within about +/−1° of normal from the plane of the substrate. Cut 302 does not extend through the entire thickness of the substrate 310.

Cut 302 creates a first cavity 306 and a second cavity 308. Some light leaks from the first cavity 306 into the second cavity 308, and the two cavities are coupled to form a coupled cavity laser. The resulting spectrum from this coupled cavity laser is a single mode wavelength.

Precision etching of a cut in accordance with an embodiment of the present invention, creates multiple FP cavities out of a single cavity. Each FP cavity exhibits multiple modes, but only one phase condition will match the resonance condition of both cavities. This limits the lasing condition to a single mode.

In making such coupled cavity lasers from a single substrate, controlling the optical phase of each cavity is important and directly affects the single mode yield. Using the FIBE process, we can control the dimensions of the gap between the cavities to an accuracy on the order of an Angstrom, a tolerance that is not generally achievable by other etching methods.

We have demonstrated such FIBE coupled cavity lasers experimentally. FIG. 3A shows a plan view of a cut into a substrate and a semiconductor stripe utilizing FIBE. FIG. 3B shows a spectrum of emission intensity versus wavelength for a coupled cavity laser fabricated in accordance with an embodiment of the present invention. The cavity emission is single mode with over 29 dB contrast between the filtered lasing mode and the nearest longitudinal mode and results from the coupled cavity effect.

FIG. 3C shows a plan view of a vertical cut in a workpiece with an adjacent hole allowing for checking of the quality of the vertical cut. The etched cut was dissected with another focused ion beam cut with a larger area, to determine the etch depth of the first cut without having to cleave through that first cut.

The fabrication of single mode semiconductor lasers in accordance with embodiments of the present invention having an emission wavelength in the range of between about 800-1650 nm is of particular relevance to current fiber optic communication applications. However, it is to understood that embodiments in accordance with the present invention are generally applicable to fabrication of single mode lasers, not limited to any particular light emitting material combination or to any specific light emission wavelength.

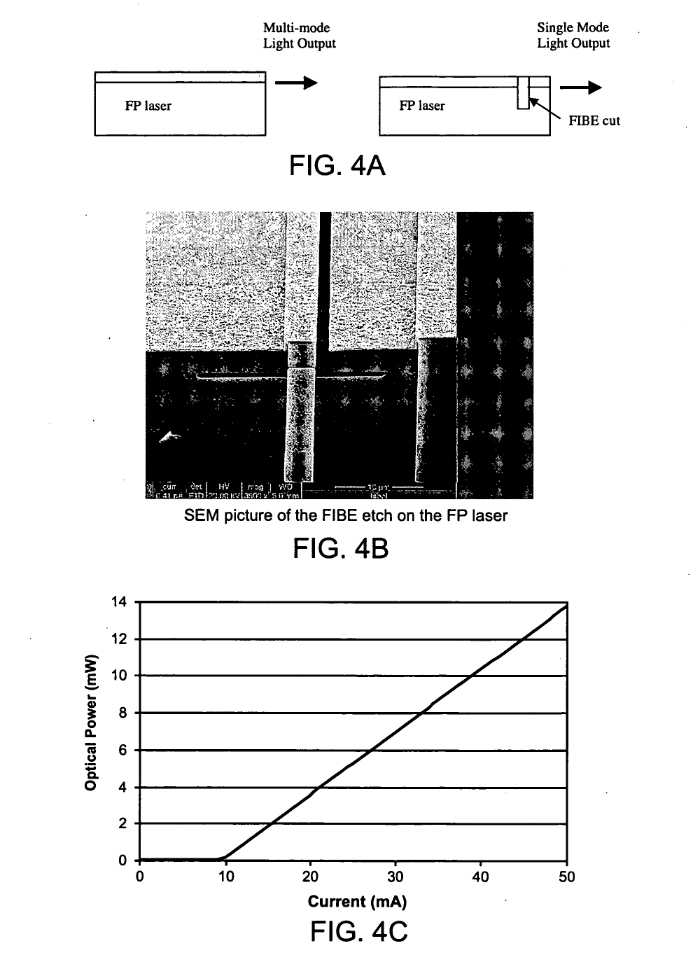

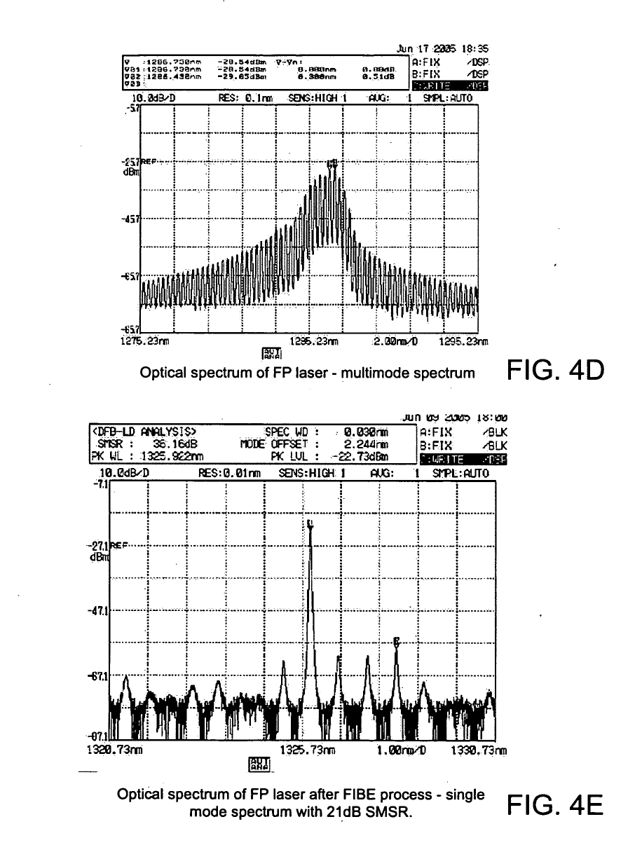

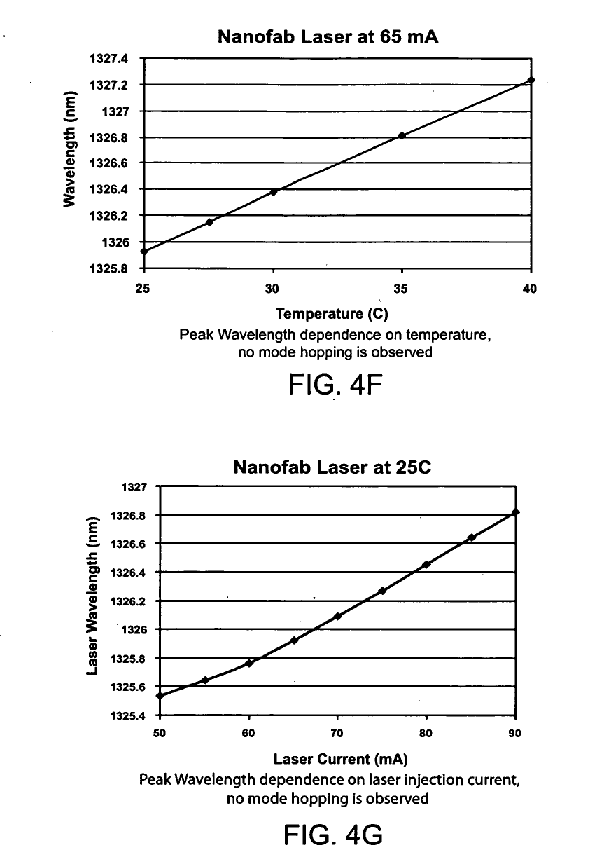

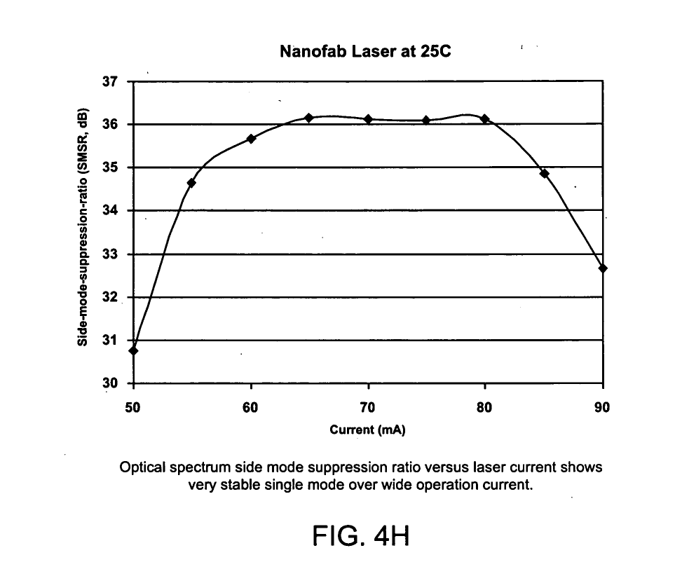

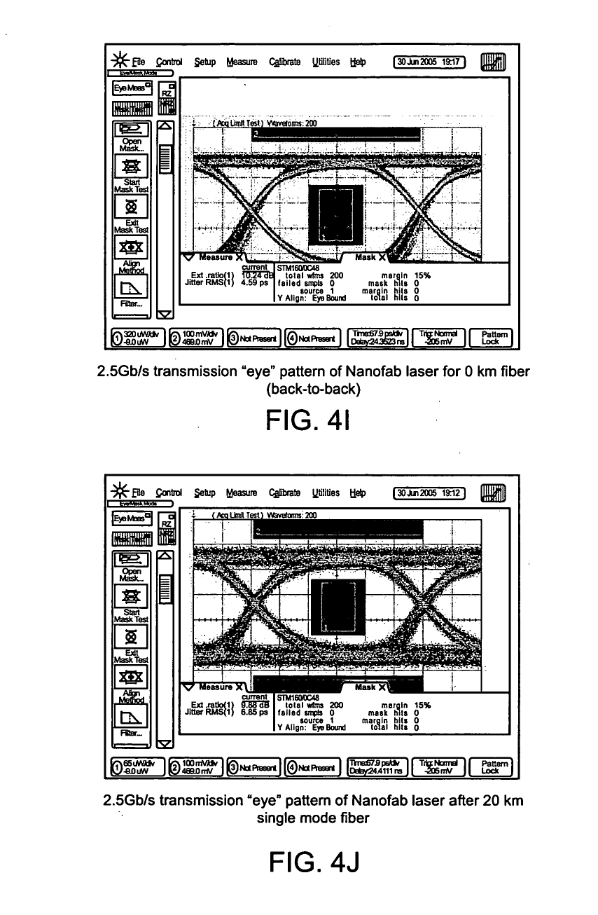

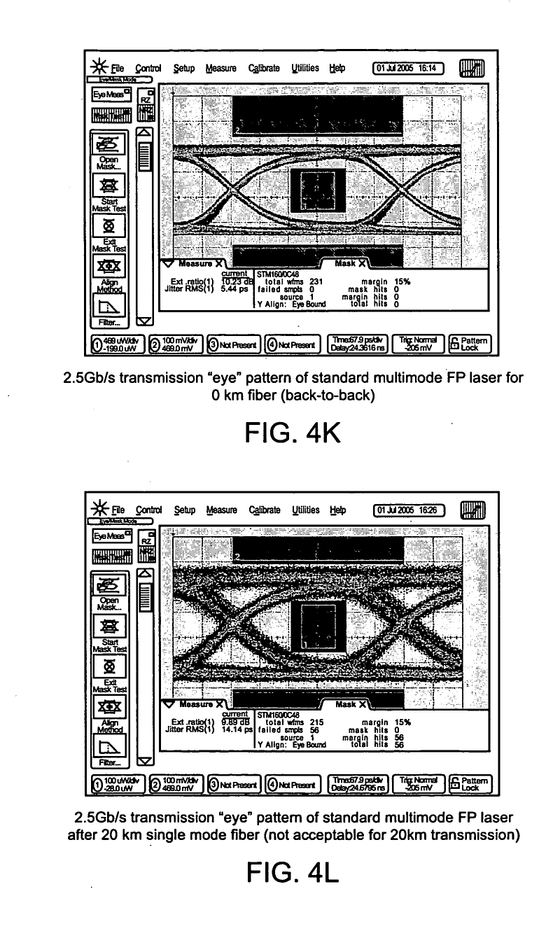

A multi-mode Fabry-Perot (FP) laser may thus be converted into a single mode laser (Nanofab Laser) in accordance with an embodiment of the present invention, by a straight substantially vertical etch cut on laser waveguide using focused ion beam etching process. A 1310 nm FP laser with 320-μm cavity length was FIBE etched substantially vertically to create a gap along the waveguide. The laser schematic diagram is shown in FIG. 4A. The scanning electron microscope (SEM) picture of the FIBE etch is shown in FIG. 4B.

For DFB lasers, the single mode yield is determined by the “Optical phases” of the two cavity mirrors, which is generally cannot be controlled by the current industry manufacturing method (cleaving). Using precision etching methods in accordance with embodiments of the present invention, we can trim the phases of the laser mirrors, and consequently improve the single mode yield, which is important in production.

We have tried a FIBE etch width from about 0.05 μm to 3 μm, with preferred devices having a cut slot width of between about 0.05 to 0.1 μm. Such a deep and narrow slot width can be achieved only by a precision etching process such as FIBE. The accuracy of etch slot width can be controlled by the FIBE parameters to as accurate as 0.1 nm.

The optical power output by the Nanofab laser is shown in FIG. 4C. The optical spectra of the laser before and after the FIBE process is shown in FIGS. 4D-E, respectively. These figures indicate that the FP (multimode) laser became a single mode laser having a single mode spectrum with 21 dB SMSR, after performance of the precision etching process in accordance with an embodiment of the present invention.

One issue associated with the Nanofab laser is the stability of the optical spectrum over temperature and laser injection current. Accordingly, the peak wavelength of output of the embodiment of the single mode laser fabricated according to the present invention, was measured over temperature and current, and the results are shown in FIGS. 4F and 4G, respectively. We do not observe any mode hopping during the temperature and current variation. As shown in FIG. 4H, the side mode suppression ratio, which indicates the quality of the single mode, is measured over 30 dB over 50 mA to 90 mA current range.

The fabricated single mode laser is then modulated at 2.5 Gb/s digital signals. FIGS. 4I-L show the resulting data transmission “eye pattern” of the signal before and after 20 km transmission. The results show that the Nanofab laser has better “eye opening” (less data transmission error) than the standard FP laser after 20 km transmission. The improvement in eye pattern is resulted from the narrowing of optical spectrum from multi-mode to single mode. Therefore, converting a multimode FP laser to a single mode laser by FIBE etch process is demonstrated and the benefit is illustrated.

The embodiment of the present invention described thus far utilizes FIBE techniques to fabricate the laser structure. FIBE etching offers precise control of the dimensions of etched features to the order of about 1 Angstrom (Å), 1×10⁻¹⁰ m. Such fine dimensional control provides the ability to control the “Optical Phase” of optical devices such as lasers and modulators. FIBE also provide flexibility in the angle and orientation of the etching, and thus in the profile of the resulting features that are formed. In contrast with other etching techniques, the FIBE process also does not require mask, enhancing the flexibility and reducing the cost of this approach.

The use of FIBE in accordance with embodiments of the present invention also results in features having low surface roughness, exhibiting, for example, surface roughness of about λ/10 or less, where λ is the wavelength of the light transmitted by the laser. In accordance with certain embodiments, the surface roughness resulting from the application of FIBE is less than about 30 nm, and preferably about 7 nm or less. The smoother the cut surface, the less light that is lost due to scattering. This surface roughness represents an average value that can be measured directly through high resolution electron microscopy or by atomic force microscopy (AFM). Alternatively, average surface roughness can be measured indirectly by sensing mirror scattering losses through mirror quality analysis of the Fabry-Perot cavity.

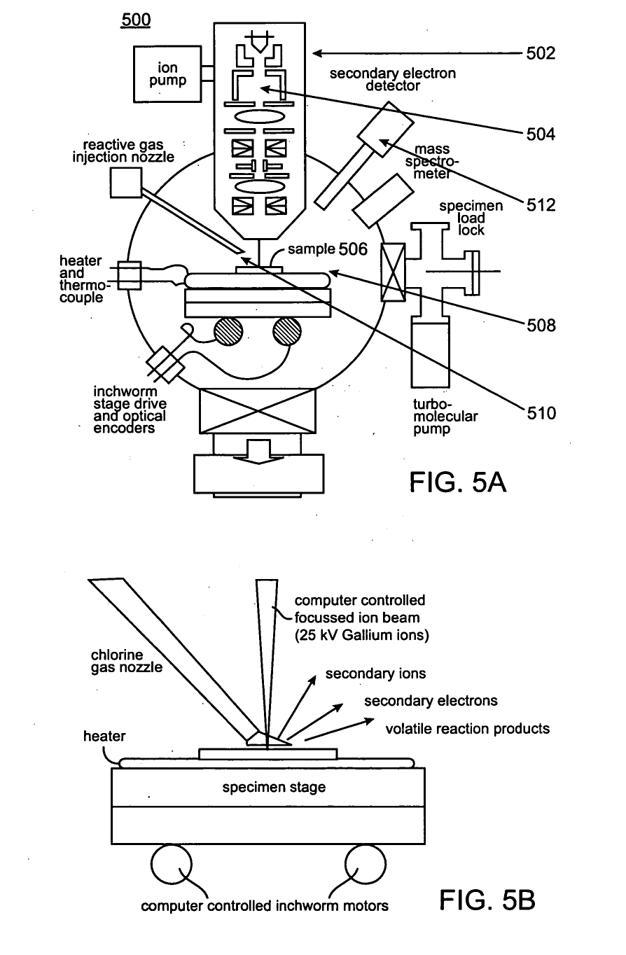

FIG. 5A shows a simplified schematic view of a system 500 for use in FIBE to fabricate an optical device in accordance with an embodiment of the present invention. Specifically, ion field extraction source 504 is maintained at a pressure of about 1×10⁻⁷ mBar, and the ion beam column 502 can focus a beam of Gallium ions to about 7-100 nm in diameter. Sample 506 is moved with a precision stage 508. Reactive gases may be introduced through narrow tube(s) 510 close to the sample to accelerate the etching process.

Secondary electrons emitted from the sample 506 may be sampled to form an image at detector 512. Specifically, FIG. 5B shows a simplified enlarged cross-sectional view of the stage and sample during the use of FIBE to form features of an optical device in accordance with an embodiment of the present invention. FIG. 5B shows that secondary ions and neutral atoms are displaced when the sample surface is irradiated by the high energy Ga beam. Reactive gases injected by tube 510 can include gases such as XeF₂, Cl₂, and organometallic materials.

While the specific embodiment described above has utilized beams of focused Gallium ions in order to etch a semiconductor stripe, this is not required by the present invention. Alternative embodiments according to the present invention could employ focused beams of other ions.

And while the specific embodiment described above involves the fabrication of a single mode laser device from a conventional multi-mode semiconductor laser stripe, the present invention is not limited to this particular application. Embodiments in accordance with the present invention are suited for fabricating a large number of different types of optical devices.

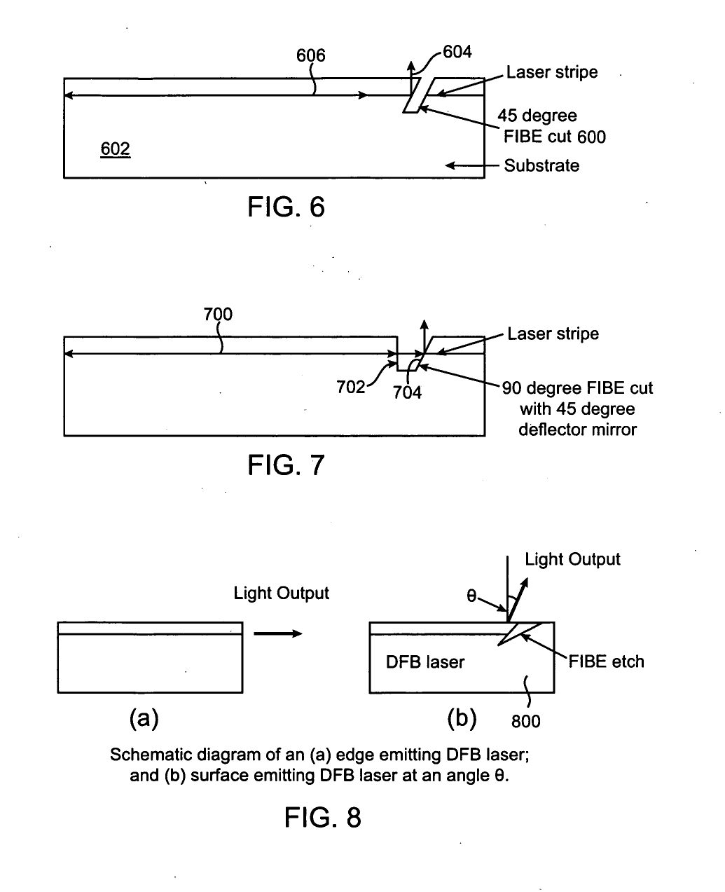

For example, another application for the use of precision etching techniques in accordance with embodiments of the present invention, involves fabrication of a vertical emitting laser diode from an edge emitting device. FIGS. 6 and 7 are simplified cross-sectional views illustrating embodiments of such an application.

FIG. 6 shows a simplified cross-sectional view of a semiconductor laser stripe etched to exhibit a feature in accordance with one embodiment of the present invention. Specifically, FIG. 6 shows performance of a 45° FIBE cut 600 on a laser diode 602 (FP or distributed feed back (DFB) lasers). Light inside the lasing cavity will be reflected through total internal reflection. It results in light 604 emitting vertical from laser waveguide 606.

Conventional long wave Vertical Cavity Surface Emitting Lasers (VCSEL) usually suffer from two problems. First, they offer relatively low optical power because of the short gain cavity. However, employing precision etching methods in accordance with embodiments of the present invention, the gain section is longer than VCSEL and similar to the conventional edge-emitting laser. Therefore, the output power is higher than VCSEL and similar to typical FP lasers.

A second problem associated with many long-wave VCSEL material systems (such as GaN materials), is difficulty lasing at wavelength shorter than 1310 nm, due to reliability issues. However, use of precision etching methods in accordance with embodiments of the present invention allows the use any semiconductor material system, including InGaAsP and InAlGaAs materials, which can provide any wavelength covering at least the 1310 nm and 1550 nm wavelength band.

Precision etching techniques in accordance with embodiments of the present invention can also be used for DBR and Distributed Bragg Reflector (DBR) lasers to generate single mode vertical emitting lasers. FIG. 7 shows a simplified cross-sectional view of a semiconductor laser stripe 700 etched to exhibit a feature in accordance with an alternative embodiment of the present invention. Specifically, FIG. 7 shows performance of a 90° FIBE cut 702 on a laser diode (FP or DFB lasers), coupled with formation of a deflector mirror 704 inclined at an angle of 45°. As described above, the 90° cut imparts single mode functionality to the laser, while the 45° mirror directs the single mode emission at an angle vertical to the semiconductor stripe.

While the above embodiment illustrates fabrication of a laser emitting at an angle perpendicular to the laser stripe, embodiments in accordance with the present invention are not limited to this or any other particular emission angle. We can flexibly and accurately control the emission angle by adjusting the parameters of the precision etching technique, for example the angle of incidence of a beam of focused ions angle can be flexibly and accurately controlled.

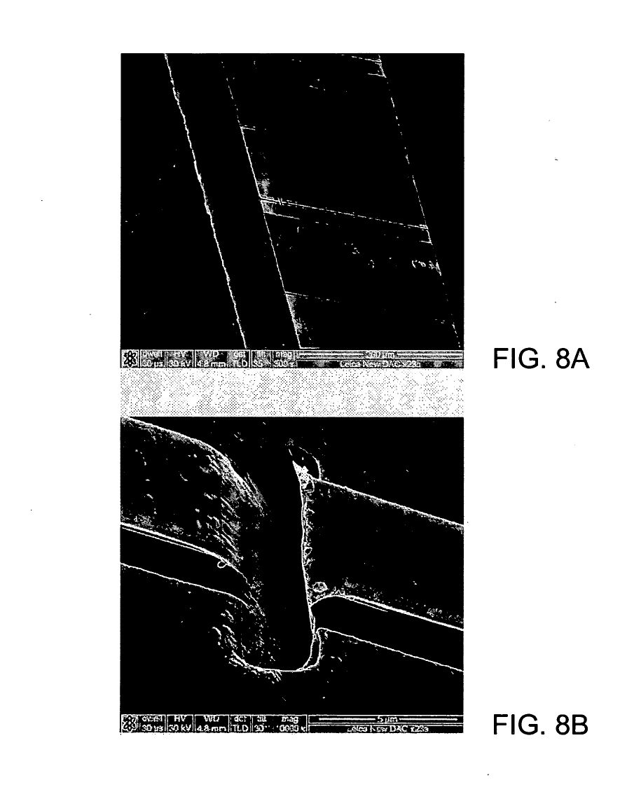

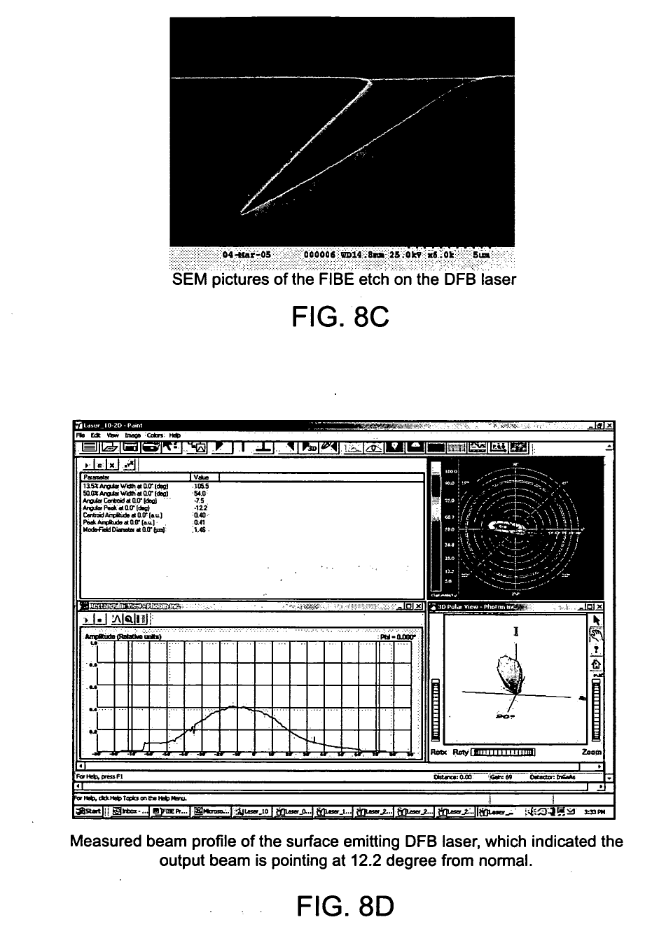

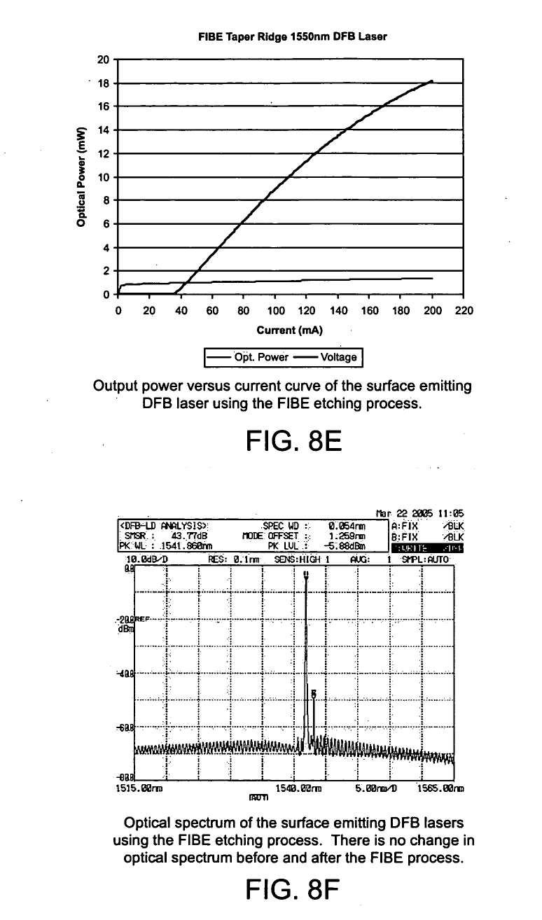

FIG. 8 shows a simplified schematic diagram contrasting the direction of emission of a conventional edge emitting laser, with a laser fabricated in accordance with an embodiment of the present invention to emit at an angle other than perpendicular to the surface of the substrate. Specifically, a 1550 nm DFB laser with 750 um cavity length was processed with FIBE at an angle θ to generate a surface emitting DFB laser 500. FIG. 8A is an electron micrograph showing a cross-section of the FIBE cut.

FIG. 8A shows a plan view of an electron micrograph of a laser stripe modified by focused ion beam cutting. FIG. 8B shows an enlarged electron micrograph of a laser stripe bearing a angled mirror etched in accordance with an embodiment of the present invention. FIG. 8C shows an electron micrograph illustrating the cross-section of the FIBE etch to create the vertically emitting laser device.

The profile of the output beam is shown in FIG. 8D, which indicates the beam pointing angle is 12.2° relative to the normal of the surface of the semiconductor stripe. The accuracy of beam pointing of the fabricated device may be controlled by the robotic stage of the FIBE equipment and the etching parameters, which can be as accurate as about 0.1°.

The optical power output from the surface emitting laser of FIG. 8 is shown in FIG. 8E. The spectrum of the emission from the laser of FIG. 8 is shown in FIG. 8F, which as expected is basically the same as the spectrum prior to subjecting the substrate to the FIBE process. Therefore, surface emitting DFB laser and accurate angular control have been demonstrated by the FIBE process.

While the specific embodiments described above have employed an angled cut formed by precision etching to change the change a direction of emission out of the plane of a substrate, this is not required by the present invention. In accordance with alternative embodiments of the present invention, angled features formed by precision etching may serve to alter a direction of emission of laser light in the same plane as the substrate.

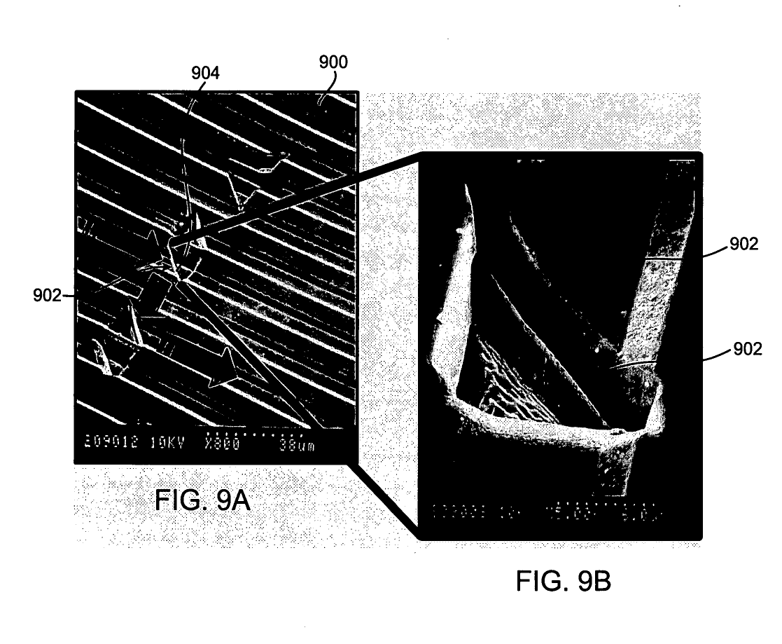

FIGS. 9A-B show plan, and enlarged plan views, respectively, of a substrate 900 containing a plurality of laser stripe waveguides 902. Angled cuts 904 formed by laser etching allow for the deflection of light from one waveguide to another, in the plane of the substrate.

While the specific embodiments described above have utilized FIBE for precision etching, this is not required by the present invention. Alternative embodiments in accordance could employ other etching techniques, and remain within the scope of the present invention. Examples of such alternate precision etching techniques include but are not limited to, photolithography to define an etch mask and subsequent Chemically Assisted Ion Beam Etching (CAIBE), reactive ion beam etching (RIBE) or very anisotropic reactive ion etching (RIE) where the sample is placed at an angle for 45 degree deflectors or flat for coupled cavity in-plane lasers. Modern inductively coupled plasma (ICP) reactive ion etching systems are ideal for this purpose.

Unlike FIBE, the CAIBE, RIBE, and RIE precision etching technique utilizes a mask to determine the location of removal of material. And while the etching action of FIBE is primarily due to the physical impingement of a tightly focused beam of ions on a small physical location, CAIBE, RIBE, and RIE rely upon chemical interaction between a less-tightly focused incident ion beam and reactive gas(es) at the surface of the etched material. This chemical reaction between ions of the beam, the reactive gases, and the target material, results in the precision etching effect. It is important to keep in mind that FIBE may also take place in the presence of reactive gases, such as hydrogen, HI or Cl₂.

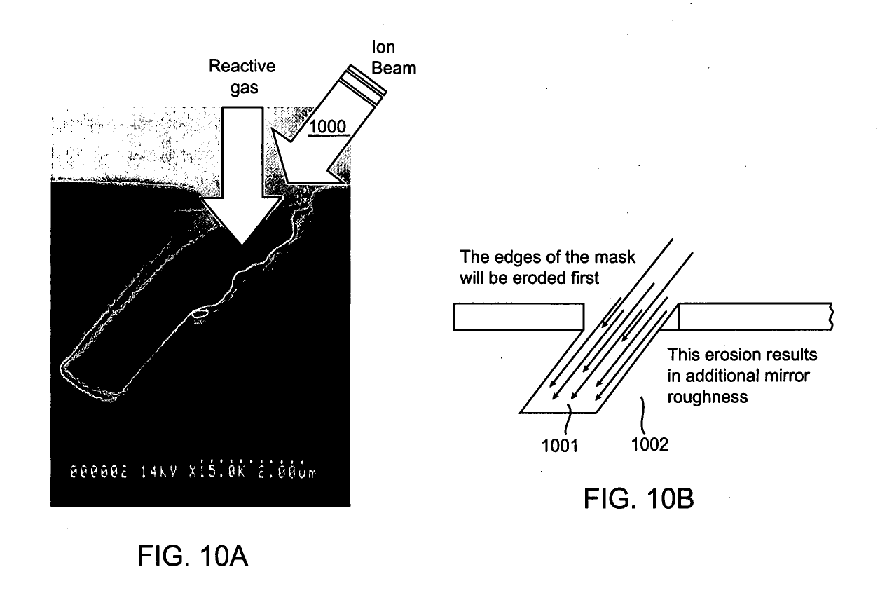

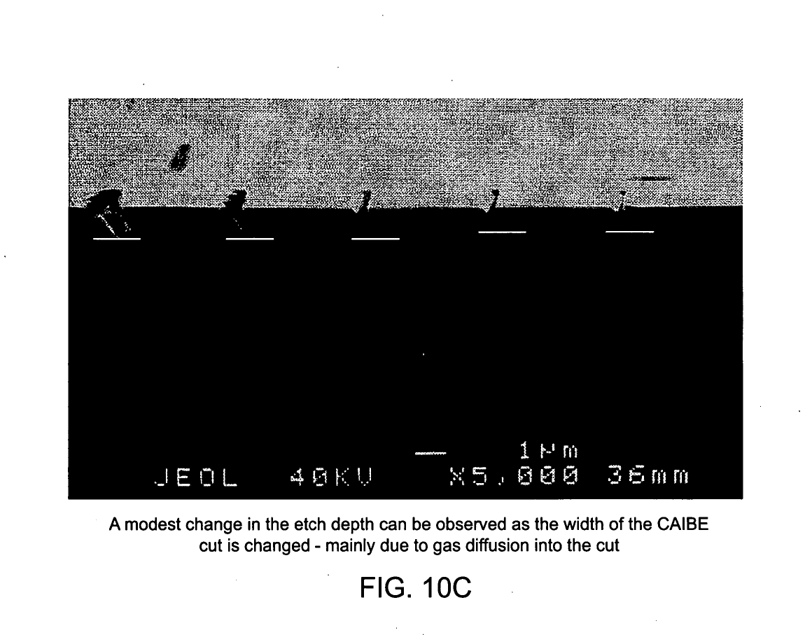

FIG. 10A shows a cross-sectional electron micrograph of a 45° mirror etched by CAIBE utilizing a beam 1000 of Ar⁺ ions. FIG. 10A shows shadowing effects due to a non-coincidence between the ion beam and the reactive gas. FIG. 10A also shows nonuniformity in etch depth due to variation in the flux of reactive gas.

FIG. 10B shows a simplified cross-sectional view of forming a cut 1001 in a substrate 1002 utilizing the CAIBE technique. FIG. 10B shows that edges of mask 1004 will be eroded first, resulting in additional roughness to the mirror. Accordingly, it is preferred that CAIBE be employed with a mask having angled sides in order to avoid roughened facets and resulting optical loss.

FIG. 10C shows an electron micrograph of the dependence of etch depth of a 45° cut etched by CAIBE, versus the width of the cut. FIG. 10C shows a modest increase in etch depth as the width of the CAIBE cut is increased, likely due to enhanced diffusion of reactive gases into the wider CAIBE cut.

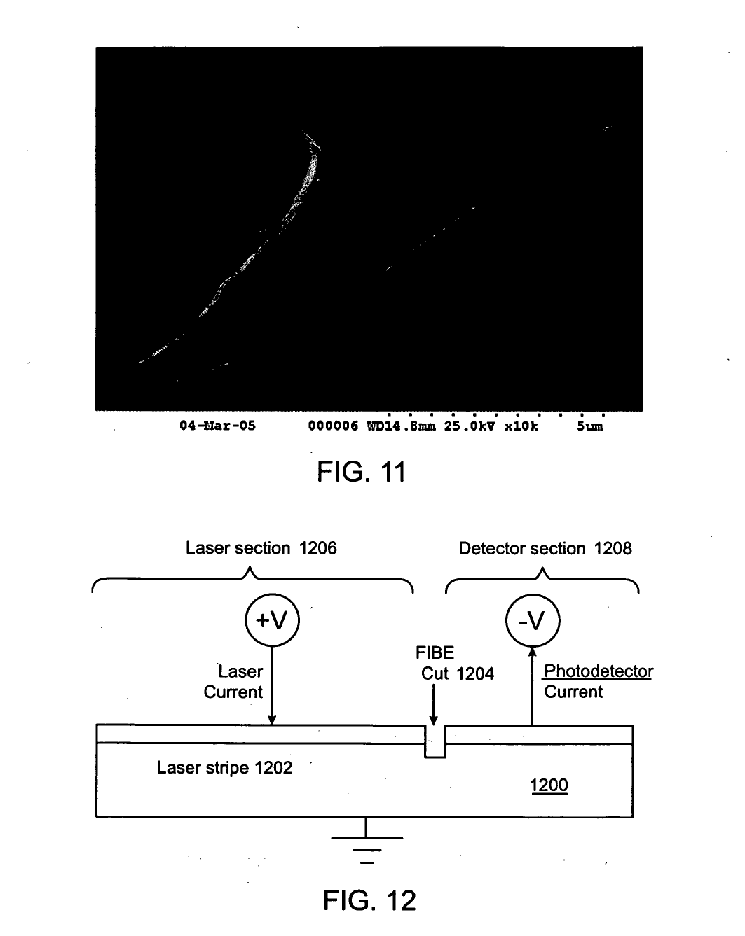

The use of precision etching processes such as CAIBE or FIBE to fabricate optical devices in accordance with embodiments of the present invention, can also allow control over the shape of the etched mirror, for example forming a curved mirror, so that the output optical beam can be either focused or defocused to fit certain applications. FIG. 11 is a cross-sectional electron micrograph showing a FIBE cut in accordance with an embodiment of the present invention exhibiting a curved surface.

Another possible application for a fabrication process in accordance with an embodiment of the present invention is to allow the integration of a detector in the same substrate as the laser. Conventionally, in most commercial laser packages a monitor photo-detector is usually needed in order to monitor output power of the laser. Using an embodiment of the FIBE method in accordance with the present invention, a channel can be cut in a semiconductor waveguide to create a laser and photo-detector sections.

FIG. 12 shows a simplified schematic view of an embodiment of a semiconductor waveguide in accordance with the present invention cut to exhibit a channel to create laser and photo-detector sections. Specifically, substrate 1200 including laser stripe 1202 is subjected to 90° FIBE cut 1204, creating laser section 1206 and detector section 1208.

In operation, laser light is generated by forward bias the laser section. Laser light emitted towards the detector section will be absorbed to generate photocurrent, which can be detected. Therefore we can integrate the laser and monitor photo-detector in a single chip by using the FIBE process, which substantially reduce the fabrication and packaging cost.

A number of other applications exist for etching methods for constructing lasers in accordance with embodiments of the present invention. For example, etching techniques in accordance with embodiments of the present invention can be employed to make low threshold or high-speed lasers. Specifically, one of the key factors for making low threshold or high speed lasers is to make the laser cavity very short. Using precise etching techniques in accordance with embodiments of the present invention, short laser cavities can be etched.

High speed lasers and low threshold lasers require very short lasing cavity. However, conventional cleaving techniques cannot consistently and reliably cleave a laser shorter than 200 μm. In accordance with one embodiment of the present invention, FIBE techniques have been employed to create a laser having a short cavity having a length of about 50 μm.

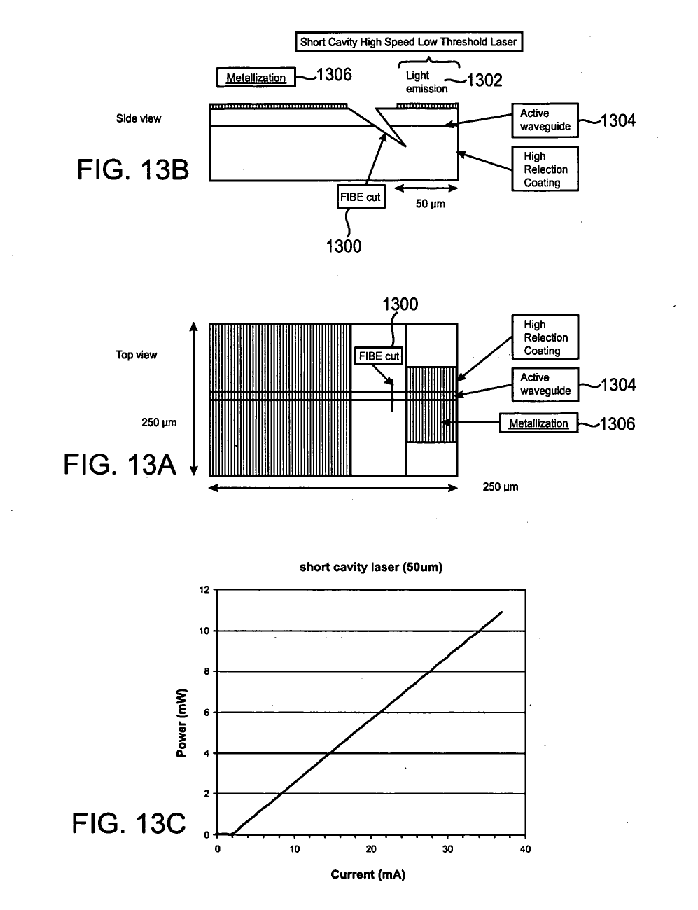

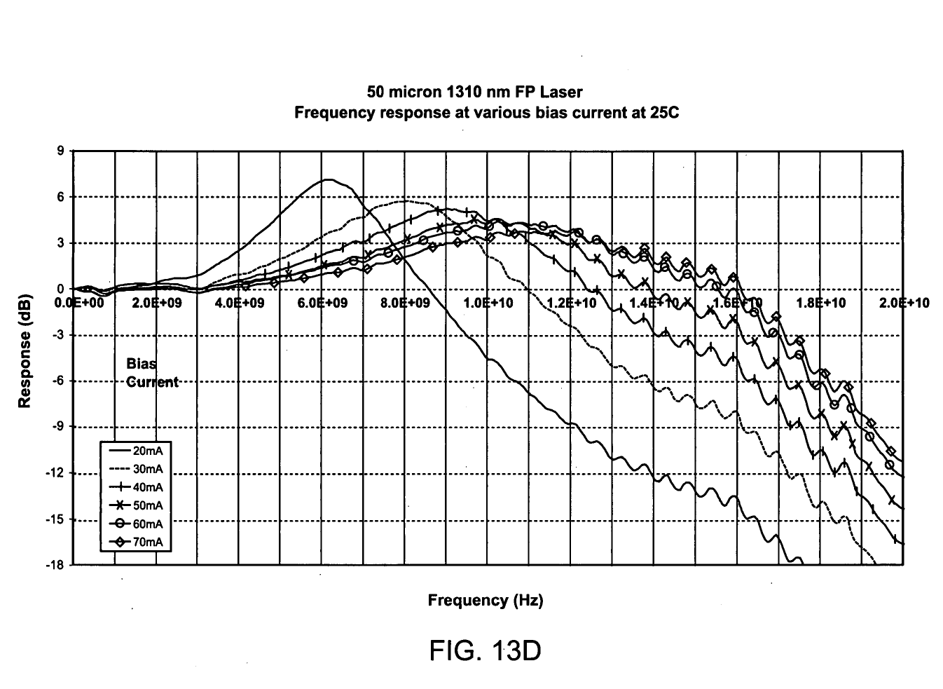

FIGS. 13A-B show simplified plan and cross-sectional views, respectively, of an embodiment of a low threshold, high speed laser fabricated according to an embodiment of the present invention. Specifically, a conventional FP laser having dimensions of 250 μm×250 μm, emitting at a wavelength of 1310 nm from its edge, was subjected to an angled FIBE cut 1300 at a distance of 50 μm from one end, in order to create a short cavity. The FIBE cut was made at 45°, so that light 1302 reflected from the waveguide 1304 was then emitted vertically from the surface. A high reflection coating 1306 was applied to the vertical cleaved facet in order to reduce the cavity loss.

FIG. 13C plots power versus current for the fabricated laser of FIGS. 13A-B. FIG. 13C shows that the threshold current of the short cavity laser was reduced to 2 mA. This 2 mA threshold current represents a reduction by about a factor of four, over the threshold current of the conventional FP laser having a cavity length of 250 μm.

FIG. 13D plots response versus frequency, at bias currents of 20 mA, 30 mA, 40 mA, 50 mA, 60 mA, and 70 mA, for the short cavity laser of FIGS. 13A-B. The 3 dB frequency response of the short cavity laser of FIGS. 13A-B was also measured to be about 16 GHz at a bias current of 60 mA. This represents an increase in speed of a factor of about three over the conventional FP laser having a cavity length of 250 μm.

Embodiments in accordance with the present invention may be useful for fabricating lasers having cavities even shorter than 50 μm. However, the output power from such devices will tend to be lower, and handling of such devices will tend to be more difficult.

FIGS. 13A-B show that the cut to fabricate the short cavity laser in accordance with an embodiment of the present invention, was made at an angle of 45° relative to the direction of the waveguide. This means that the output laser beam is emitting vertically from the surface, and thus the short cavity laser is also a surface emitting laser.

Still another application for laser construction methods in accordance with embodiments of the present invention is in the creation of tunable lasers. Using precise etching, we can etch the Distributed Bragg Reflector (DBR) grating waveguide to form a multi-section laser.

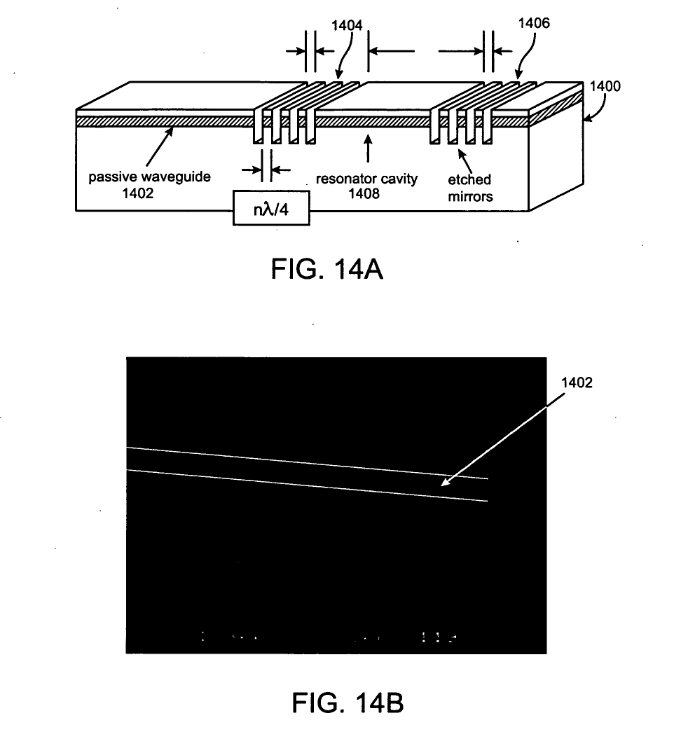

FIG. 14A shows a simplified cross-sectional view of one embodiment of such an application for optical devices fabricated in accordance with an embodiment of the present invention. FIG. 14B shows an electron micrograph of the embodiment of FIG. 14A. Substrate 1400 includes passive waveguide 1402 and two sets of mirrors 1404 and 1406, each formed by cuts having a width of nλ/4. Mirrors 1404 and 1406 are defined by the alternating portions of air and semiconductor material exhibiting contrasting refractive indices. Particularly useful embodiments in accordance with the present invention employ air-filled cuts having a width of 1λ/4, separated by InP semiconductor material having a width of 5λ/4.

The section 1408 between mirrors 1404 and 1406 defines a resonator cavity. By assembling a laser comprising multiple sections, and controlling the injection current to each section, we can tune the laser to various wavelengths. Once again, the ability to control the phase of the device is important to achieve a high yield process.

Yet another application for laser construction methods in accordance with embodiments of the present invention is to simplify laser packaging. FIBE or other precision etching techniques can be used to etch a desired lens profile on the laser substrate so that the packaging cost can be reduced.

It is important to note that the etching techniques in accordance with embodiments of the present invention can be applied to fabricate a laser from any semiconductor material. This allows construction of lasers including the typical communication wavelength of 850 nm, 1310 nm, and 1550 nm.

In conclusion, embodiments in accordance with the present invention relate to materials processing methods utilizing high resolution precision etching techniques such as “Focus Ion Beam Etching (FIBE)”, developed and applied to the construction of high quality lasers. To the best of our knowledge, this is the first time FIBE has been applied to folded cavity semiconductor laser fabrication. We believe this fabrication technology will revolutionize the fabrication of future semiconductor lasers with single mode spectral output characteristics.

It is understood that the examples and embodiments described herein are for illustrative purposes only, and there can be other variations and alternatives. Various modifications or changes in light of the above description thereof will be suggested to persons skilled in the art and are to be included within the spirit and purview of this application and scope of the appended claims.

1. A semiconductor laser device comprising:
a substrate including a diode in optical communication with a waveguide, the waveguide oriented along a plane of the substrate; and
a cut in a surface of the substrate extending through the waveguide, the cut forming a first cavity and a second cavity, the cut exhibiting a surface roughness of λ/10 or less, where ÿ comprises a wavelength of a single mode of light emitted from the diode and optically communicated from the first cavity to the second cavity.

2. The device of claim 1 wherein the cut is within about +/−6° of normal from the plane of the substrate.

3. The device of claim 1 wherein the single mode of light corresponds to a phase condition matching a first resonance condition of the first cavity and a second resonance condition of the second cavity.

4. The device of claim 1 wherein a surface roughness of the cut is less than about 30 nm.

5. The device of claim 1 wherein the cut does not extend through an entire thickness of the substrate.

6. The device of claim 1 wherein the cut has a width of from about 0.05-3 μm.

7. The device of claim 6 wherein the width of the cut is between about 0.05-1 μm.

8. The device of claim 1 wherein the diode is configured to emit light having the wavelength of between about 800-1650 nm.

9. The device of claim 1 wherein the substrate comprises at least one of InP, InGaAs, InGaAsP, GaAs, AlGaAs, InGaP, InGaAlP, InGaN, and AlGaN.

10. A method of fabricating a single mode laser, the method comprising:
providing a substrate including a diode in optical communication with a waveguide, the waveguide oriented along a plane of the substrate; and
forming a cut in a surface of the substrate utilizing a precision etching technique, the cut extending through the waveguide to form a first cavity and a second cavity, the cut exhibiting a surface roughness of λ/10 or less, where λ comprises a wavelength of a single mode of light emitted from the diode and optically communicated from the first cavity to the second cavity.

11. The method of claim 10 wherein the cut is formed by a Focused Ion Beam Etching (FIBE) precision etching technique.

12. The method of claim 11 wherein a focused beam of Gallium ions is directed against the substrate to form the cut.

13. The method of claim 11 wherein a focused beam of ions is directed against the substrate in a direction substantially vertical to the plane of the substrate.

14. The method of claim 11 wherein the focused beam of ions is directed against the substrate in a presence of a reactive gas is selected from the group comprising hydrogen, HI, XeF₂, Cl₂, and an organometallic.

15. The method of claim 10 wherein the cut is formed by a Chemically Assisted Ion Beam Etching (CAIBE) precision etching technique.

16. The method of claim 15 wherein a beam of Argon ions is directed against the substrate in a presence of a reactive gas in order to form the cut.

17. The method of claim 10 wherein the precision etching technique employs a beam spot having a diameter of between about 0.7-100 nm.

18. The method of claim 10 wherein the cut is formed with a surface roughness of about 30 nm or less, and with a width of between about 0.05-3 μm.

19. A method of fabricating a single mode laser, the method comprising:
providing a Fabry-Perot edge emitting multi-mode laser having a waveguide; and
forming a cut through the waveguide utilizing a precision etching technique to form a first cavity and a second cavity, the cut exhibiting a surface roughness of λ/10 or less, where λ comprises a wavelength of a single mode of light emitted from a diode optically coupled with the waveguide and optically communicated from the first cavity to the second cavity.

20. The method of claim 19 wherein the cut is formed by a precision etching technique selected from the group comprising Focused Ion Beam Etching (FIBE), Chemically Assisted Ion Beam Etching (CAIBE), photomasking and reactive ion etching (RIE), and reactive ion beam etching (RIBE).
